(19) United States
(12) Patent Application Publication
(10) Pub. No.: US 2023/0237795 A1
(43) Pub. Date: Jul. 27, 2023

(54) OBJECT PLACEMENT VERIFICATION

(71) Applicant: Ryan Mark Van Niekerk, New Braunfels, TX (US)

(72) Inventors: Ryan Mark Van Niekerk, New Braunfels, TX (US); Matthew Thomas Smith, Austin, TX (US); Ethan Wayne Blagg, Austin, TX (US)

(21) Appl. No.: 17/581,585

(22) Filed: Jan. 21, 2022

(51) Int. Cl. G06V 20/10; G06V 20/17; G06F 30/13; B64C 39/02

(52) U.S. Cl. CPC G06V 20/176; B64C 39/024; G06F 30/13; G06V 20/17; B64C 2201/123

(57) ABSTRACT

Described are approaches for monitoring construction of a structure. In an embodiment, sensor data (e.g., imaging data, LIDAR, infrared, etc.) of a construction site is obtained. The sensor data is analyzed and objects related to the construction site are identified. The objects are mapped to corresponding objects of a builder’s design plans of the construction site, and the location of components are checked for accuracy. When a discrepancy above a threshold is detected, a report indicating such errors is generated and appropriate entities are provided the report.

### BACKGROUND

Constructing physical structures, such as buildings, requires the proper installation/assembly of many components. For example, some complex structures have thousands of components that need to be installed with a location accuracy of within an eighth of an inch, or even less in some cases. Construction workers needs to properly locate and install/assemble an incredible number of components, such as pipe sleeves, beams, pipes, ducts, studs, walls, etc.

Unfortunately, conventional construction processes are subject to errors, which can cause significant amounts of re-work and schedule delay. For example, a pipe sleeve may be installed at a wrong location. If the error is not detected in a timely fashion, a significant amount of re-work may result. A contractor may lay concrete over improperly run pipe sleeves, a plumber may run water lines through the improperly located wall, an electrician may run electrical wires through the improperly located wall, a carpenter may add sheetrock to the improperly located wall, etc. When the error is detected, the wall, concrete, etc., may need to be demolished and rebuilt in the proper location in order to rectify the error, and the pipe sleeves, water lines, electrical wires, sheetrock, etc. may need to be reinstalled. Such errors may cause significant schedule delays and may result in significant additional costs for the construction project.

### SUMMARY

Systems and methods in accordance with various embodiments of the present disclosure may overcome one or more of the aforementioned and other deficiencies experienced in conventional approaches to monitoring construction of a structure or other physical environment. In an embodiment, sensor data (e.g., imaging data, LIDAR, infrared, etc.) of a construction site is obtained. The sensor data is analyzed and objects related to the construction site are identified. The objects are mapped to corresponding objects of a builder’s design plans of the construction site, and the location of components are verified for accuracy. When a discrepancy above a threshold is detected, a report indicating such discrepancies can be generated and appropriate entities notified.

Instructions for causing a computer system to facilitate the monitoring of a structure in accordance with the present disclosure may be embodied on a computer-readable medium. For example, in accordance with an embodiment, a backend system may obtain sensor data of a construction site is obtained. The backend system can the sensor data and objects related to the construction site are identified. The backend system maps the objects to corresponding objects of a builder’s design plans of the construction site, and the location of components are verified for accuracy. When a discrepancy above a threshold is detected, a report indicating such discrepancies can be generated and appropriate entities notified.

It should be noted that although the techniques described herein may be used for a wide variety of construction/building projects, for clarity of presentation, examples of construction sites will be used. The techniques described herein, however, are not limited to construction sites, and can include other physical locations where the construction of, for example, vehicles, airplanes, ships, organic tissue, land scaping, sports facilities, parking lots, etc., is accomplished.

Embodiments provide a variety of advantages. For example, in accordance with various embodiments, present invention reduces time and costs associated with construction when compared to conventional construction approaches. Further, such approaches may be utilized by various industries, including, for example, construction, building, health, robotic, among other such industries were monitoring the construction of a structure or physical environment is desirable.

Various other functions and advantages are described and suggested below as may be provided in accordance with the various embodiments.

### BRIEF DESCRIPTION OF THE DRAWING FIGURES

The accompanying drawings illustrate several embodiments and, together with the description, serve to explain the principles of the invention according to the embodiments. It will be appreciated by one skilled in the art that the particular arrangements illustrated in the drawings are merely exemplary and are not to be considered as limiting of the scope of the invention or the claims herein in any way.

FIG. 1A illustrates an example environment in which various embodiments can be utilized.

FIG. 1B illustrates an example of a report in accordance with an embodiment.

FIG. 2 illustrates an example environment in which aspects of the various embodiments can be implemented.

FIG. 3 illustrates an example of an object placement verification system in accordance with an embodiment.

FIG. 4 illustrates an example reporting system in accordance with an embodiment.

FIG. 5 illustrates an example process for determining training data that can be used in accordance with various embodiments;

FIG. 6 illustrates an example process for training a model that can be utilized in accordance with various embodiments;

FIG. 7 illustrates an exemplary embodiment of a training system in accordance with an embodiment.

FIG. 8 illustrates an exemplary process for object location verification according to an embodiment.

FIG. 9 illustrates components of a computing device that supports an embodiment of the present invention.

FIG. 10 illustrates an exemplary architecture of a system that supports an embodiment of the present invention.

FIG. 11 illustrates another exemplary architecture of a system that supports an embodiment of the present invention.

FIG. 12 illustrates components of a computer system that supports an embodiment of the present invention.

### DETAILED DESCRIPTION

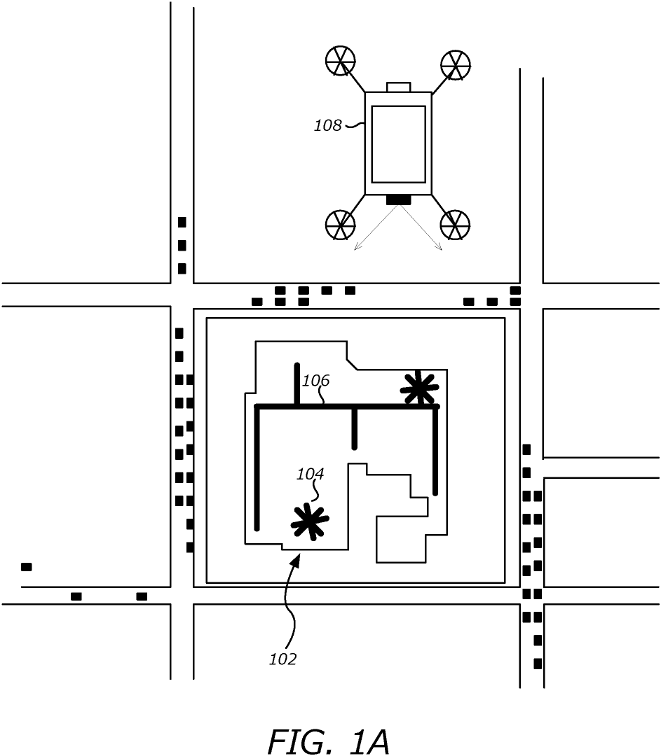

FIG. 1A illustrates an example environment in which various embodiments can be utilized. The environment shows a real-world environment of a construction site 102 with a few physical, real-world objects on it. One of those objects is a marker 104. Marker 104 may include different types of objects. For example, a marker 104 can be a pattern as shown, an object, a quick response (QR) code, a barcode, a grid, a colored grid, a physical object, a physical marking, non-physical markings including those using lasers, LiDAR, sound, geo-tagging, or any other object with known dimensions. In some embodiments, the marker can be created by a user. For example, a user can place the marker or cause the marker to be placed in a location. Another one of the objects comprises pipe sleeve 106. The objects can include items typically found at a construction site, including for example structural beams, floors, walls, plumbing, electrical wiring, door frames and doors, landscaping, walkways, buildings, building foundations, construction equipment, construction tools, etc.

During the process of constructing a building or other structure, the process starts with designing the building and planning the construction of the building. The process of designing the building includes capturing the design of the building via one or more computer-aided-design (CAD) applications. A CAD application can be a three-dimensional (3D) CAD application, a two-dimensional (2D) CAD application, among others. For example, the design of the supporting structure of the building may be captured via a 3D CAD application that supports structural analysis, such as by determining the effects of loads and stresses on structures and their components. The plumbing design may be captured via a 3D CAD application optimized for analysis and construction of plumbing components. The electrical wiring design may be captured via a 2D CAD application optimized for analysis and construction of electrical components. In an embodiment, the captured data comprises the construction site data.

Once the construction project is under way, construction crews attempt to construct the building as indicated by the building design data captured by the various CAD applications. However, in some cases during construction, the dimensions and/or location of an object may be incorrect with respect to the building design planes. For example, a pipe sleeve may be incorrectly positioned. If the error is not noticed early in the construction process, concrete may need to be demolished and the pipe sleeve placed in the proper location in order to rectify the error. Such errors may cause significant schedule delays and may result in significant additional costs for the construction project.

Accordingly, in accordance with various embodiments, sensor data that includes representations of one or more objects at a construction site is obtained. In an embodiment, the sensor data can be obtained by an unmanned aerial vehicle (UVA). Although UVA 108 is shown, it should be understood that any device capable of receiving, determining, and/or processing input can be used in accordance with various embodiments discussed herein, where the devices can include, for example, drones, robots, satellites, airplanes, a person with a device operable to capture sensor data, or another data capture device. In an embodiment, the sensor data can include two-dimensional sensor data (e.g., still images and/or video data), three-dimensional point data, RFID, radar data, depth data, GPS data, infrared, light coding, LIDAR, etc.

The sensor data and the construction site data is analyzed to identify the various objects of building depicted in the views, and maps the objects represented in the sensor data to corresponding objects represented in the construction site data. The data is analyzed to detect discrepancies between objects of the two views. For example, in the example where a pipe sleeve is installed at an incorrect location, the pipe sleeve represented in the sensor data is mapped to the corresponding pipe sleeve represented in the construction site data. A determination is made based on the mapping that a location of the installed pipe sleeve is not located as indicated by the construction site data. That is, a determination is made that the installation discrepancy is above a predetermined threshold.

A report and/or notification can be provided to a user or other appropriate entity relating to any discrepancies. The report can be provided to one or more authorized users and/or accounts. In an embodiment, a report or notification may inform a user that a location of an object represented in sensor data is different from the location of the corresponding object represented in the construction site data. In an embodiment, the report may indicate the discrepancy. For example, FIG. 1B illustrates an example of a report that may highlight, emphasis text, add text or graphics, etc., to indicate any discrepancies. In this example, the report identifies discrepancy 142 and discrepancy 144. Continuing with the above example, discrepancy 142 and discrepancy 144 can correspond to a pipe sleeve being installed in an incorrect location.

In an embodiment, the report may identify objects for review. In some embodiments, the interface may include a widget (e.g., graphical button) that allows a user to preview at least information 146 about any discrepancies. Still in other embodiments, a navigation or mapping application may be utilized to help a user navigate to one or more locations associated with a discrepancy. For example, the navigation application may provide as an overlay to the construction site a graphical icon 150 representing a user’s current position and a path 148 to the discrepancy. Continuing with this example, the navigation application can provide visual and/or audible content to assist a user in reaching a location of the discrepancy.

Advantageously, as a result of the error in the location of the pipe sleeve being caught early, the error is remedied before additional work has begun, resulting in a significant reduction in the impact of the error on the schedule and costs of the construction project. By timely detecting the error, the location of the pipe sleeve can be fixed before any subsequent construction involving the pipe sleeve is started, resulting in avoidance of re-work of the subsequent construction. For example, by detecting the error of the location of the pipe sleeve early, the pipe sleeve can be before any cement work is started. Embodiments further provide improved accuracy construction progress status. For example, as a result of detecting discrepancies in a timely fashion, the disclosed technique can improve upon existing progress status evaluation techniques. Embodiments can further provide for improved accuracy construction schedule and cost estimation. In some embodiments, the disclosed technique enables earlier detection of errors or discrepancies, improved accuracy monitoring of construction progress, and improved accuracy project schedule or cost estimations.

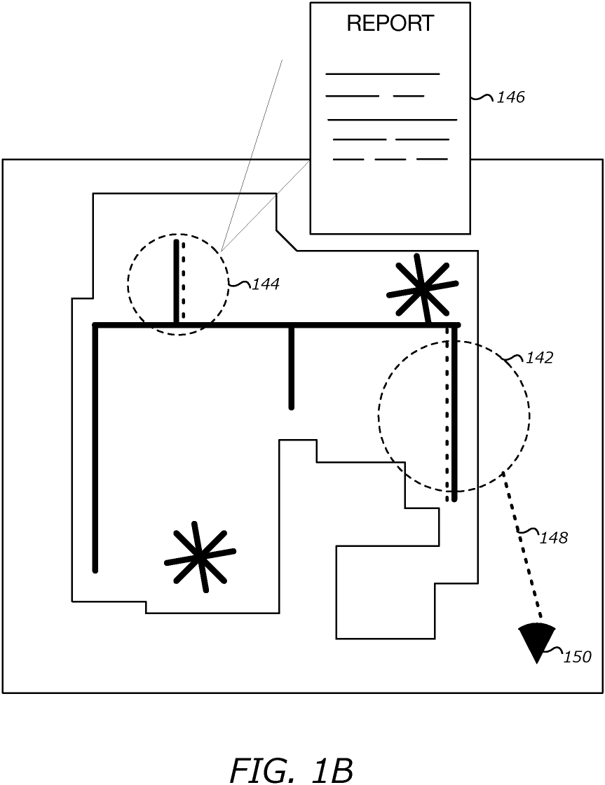

FIG. 2 illustrates an example environment in which aspects of the various embodiments can be implemented. As shown, object placement verification system 220, training system 230, reporting system 240, and client device(s) 260 communicate and interact via network 250 to facilitate the verification of the placement of objects in a physical environment. It should be known that the various components described herein are exemplary and for illustration purposes only. The components may be reorganized or consolidated, as understood by a person of ordinary skill in the art, to perform the same tasks on one or more other servers or computing devices without departing from the scope of the invention. Other components and interfaces may be used, as would be readily understood by a person of ordinary skill in the art, without departing from the scope of the embodiments described herein.

Object placement verification system 220 is configured to verify a location and/or position of a physical object in a real-world environment. In an embodiment, object placement verification system 220 analyzes sensor data (e.g., ortho mosaic sensor data) that includes representations of one or more objects and determines whether the location of those objects is correct. As described herein, the term “objects” may be used interchangeably with the term “items” for ease of explanation.

In an embodiment, object placement verification system 220 obtains sensor data that includes a representation of a physical environment. The sensor data can be obtained from an unmanned aerial vehicle (UVA), satellite, airplane, or another image capture device. The sensor data can include two-dimensional data, three-dimensional point data, RFID, radar sensor data, depth data, GPS data, infrared, light coding, LIDAR, etc. The physical environment can include a construction site. The construction site can include one or more objects, markers, etc. The objects can include items typically found at a construction site, including for example, structural beams, floors, flooring, walls, plumbing, electrical wiring, fire sprinklers, door frames and doors, landscaping, walkways, buildings, building foundations, construction equipment, construction tools, etc. The markers can include physical objects such as a structure, physical markings, non-physical markings including those using lasers, LiDAR, sound, geo-tagging, and the like. The markers can be associated with dimensions. For example, the length, width, and height of the marker is known. The markers can be associated with GPS coordinates or other position coordinates that can be used to identify a geographic location of the maker.

Herein, for the ease of explanation, a “real-world environment” will refer to a physical environment, wherein physical objects are present. The term “camera environment” will refer to an environment shown on the display of a computing device or interface, which will typically include an image of a real-world environment and one or more 2D or 3D objects inserted into the environment. In other words, to simplify the explanation of various embodiments discussed in this application, the term “real-world environment” will be used to describe the environment in which a user may utilize an electronic device to capture and view images, and the term “camera environment” will be used to describe the environment shown on the display of the computing device, which may include an image of the real-world environment with an image of a superimposed object (e.g., objects from building plans).

Moreover, herein the term “pose” of an object with respect to another object can refer to the position and orientation of an object with respect to another object. For example, a computing device may determine the pose of a container, box, structure, marker, or other object with respect to the computing device, based at least in part on an image captured by the computing device. Additionally, the pose of a computing device may be based at least in part on data associated with the computing device with respect to another object such as a marker. Further, the pose of a computing device, or another object, may be based at least in part on data derived from components within a computing device, such as a gyroscopic sensor, an accelerometer, and/or a location determination component. For example, the pose of a computing device may be determined at least in part on the location of the device and/or the direction of g (also referred to as “little g”), which is the direction of the downward force associated with gravity and can be used to determine the orientation of a computing device.

The sensor data can be analyzed using at least one object recognition algorithms that utilize various models to recognize a physical object and marker. In accordance an embodiment, a model can be trained to recognize a type of object. In an embodiment, there may be a plurality of object recognition algorithms, each algorithm trained for a different type of object. In certain embodiments, the object recognition algorithm can be trained for a plurality of different types of objects. In a specific example, the object recognition algorithm can be trained to recognize pipes. In another example, the object recognition can be used to recognize one or more markers.

Object placement verification system 220 can obtain construction site data for the construction site. The construction site data can include design plans associated with the construction site, a representation of an object, and a representation of a reference marker. In an embodiment, the design plans can include the construction site data including, for example computer-aided design (CAD) data. In an embodiment, the CAD data can specify the physical properties (e.g., dimensions) of the object. In an example, the CAD data can specify the length of a pipe sleeve, the width of the pipe sleeve, etc. In an embodiment, the CAD data can specify a label that describes the type of object. For example, the CAD data can specify a label “pipe sleeve,” indicating that the object is a pipe sleeve. The CAD data can specify the dimensions of the marker. It should be noted that files suitable to upload and convert into a representation of an object may include, but are not limited to: image files, video files, files generated by a scanner, and computer aided design (CAD) files (e.g., .obj files, .stl files, .cad files).

Object placement verification system 220 can use an image processing technique to transform or otherwise map the sensor data and the construction site data to a common coordinate system. This allows for matching points between the sensor data and the construction site data. Said another way, given sensor data of the physical environment, and construction site data of the physical environment, a set of points in the sensor data can be identified as the same points in the construction site data. Continuing with this example, points or features in the sensor data can be matched with the corresponding points or corresponding features in the construction site data. In an example, the set of points or features in the sensor data can correspond to the marker represented in the sensor data and the corresponding points or corresponding features in the construction site data can correspond to the marker represented in the construction site data.

Object placement verification system 220 can then determine the similarity or correspondence between objects (e.g., pipe sleeve) represented in the sensor data with corresponding objects represented in the construction site data. Determining the similarity or correspondence in various embodiments includes determining an offset between corresponding objects. Said another way, object placement verification system 220 can execute a spatial verification technique in which a location of an object represented in the sensor data is compared to a location of a corresponding object represented in the construction site data to determine an offset or discrepancy between object locations. For example, once the sensor data is aligned and/or mapped with the construction site data based on corresponding markers represented in the sensor data and the construction site data, the correspondence between a pipe sleeve represented in the sensor data and a corresponding pipe sleeve represented in the construction site data can be determined. This can include, for example, determining where the pipe sleeve represented in the sensor data overlaps the pipe sleeve represented in the construction site data. This can further include determining how far off (e.g., the offset or discrepancy) between the pipe sleeve represented in the sensor data is from the pipe sleeve represented in the construction site data. In an embodiment, the offset or discrepancy can correspond to a physical distance, including, for example, a physical offset.

The offset can then be used to determine whether an object (e.g., pipe sleeve) represented in the sensor data is correctly positioned. For example, once object placement verification system 220 determines spatio-temporal differences or an offset between the object represented in the sensor data and the corresponding object represented in the construction site data. In a specific example, the offset can be compared to a threshold. In the situation the offset fails to satisfy the threshold, the object represented in the sensor data may not be in the correct location. That is, the physical object represented in the sensor data may not be in the correct physical location. In the situation the offset satisfies the threshold, the object represented in the image may be in the correct location. That is, the physical object represented in sensor data is in the correct physical location.

Object placement verification system 220 can provide location verification services to various industries. The industries can include, for example, construction industries, building industries, government industries, security industries, among other such industries. In an embodiment, object placement verification system 220 can include any appropriate components for verifying object placement in a physical environment. Object placement verification system 220 might include Web servers and/or application servers for recognizing objects in an image, and verifying the location and/or position of the object.

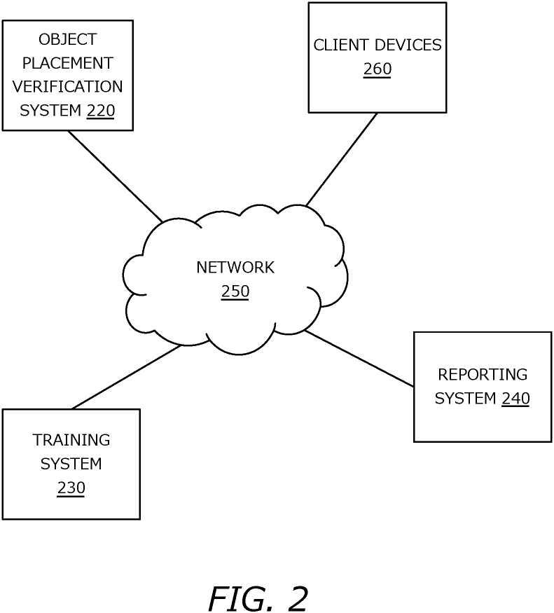

In various embodiments, object placement verification system 220 may include various types of resources that can be used to verify the location and/or position of a physical object in a physical environment. The resources can include, for example, application servers operable to process instructions provided by a user or database servers operable to process data stored in one or more data stores in response to a user request. The resources may be hosted on multiple server computers and/or distributed across multiple systems. Additionally, the components may be implemented using any number of different computers and/or systems. Thus, the components may be separated into multiple services and/or over multiple different systems to perform the functionality described herein. In some embodiments, at least a portion of the resources can be “virtual” resources supported by these and/or components. Object placement verification system is described in greater detail below in reference to FIG. 3.

Training system 230 is operable to build models and feature(s) for the models to recognize one or more objects types represented in the sensor data. The models or feature(s) can be generated using images of different types of objects. For example, a trained model can recognize one of a number of objects from the image training data. With respect to construction sites, a trained model can be used to generate features that can be used to recognize an object at a construction site, such as a pipe. In this example, the trained model can include a confidence value for recognizing the object. The feature can be compared to an appropriate threshold to determine whether the confidence level for the object is sufficient.

Reporting system 240 is operable to provide reports and/or notifications to a user or other appropriate entity relating to any discrepancies between objects represented in the sensor data and objects in the construction site data. The report can be provided to one or more authorized users and/or accounts. In an embodiment, a report or notification may inform a user that a location of an object represented in sensor data is different from the location of the corresponding object represented in the construction site data. In an embodiment, the report may indicate the discrepancy. For example, the report may highlight, emphasis text, add text or graphics, etc., to indicate any discrepancies. The report may identify objects for review. In an embodiment, the report may provide a reason and/or solution for the discrepancy. The reports and/or notifications may be presented to a user via a computing device such as a content server or another appropriate computing device.

A user can utilize client device 260 to communicate across at least one network 250 with object placement verification system 220, reporting system 240, and/or training system 230. The client device 260 can include any appropriate electronic device operable to send and receive requests or other such information over an appropriate network and convey information back to a user of the device. Examples of such client devices 260 include personal computers, tablet computers, smartphones, notebook computers, and the like. The user can include a person authorized to access object placement verification system 220.

Client devices may include, generally, a computer or computing device including functionality for communicating (e.g., remotely) over a network 250. Data may be collected from client devices, and data requests may be initiated from each client device. Client device(s) may be a server, a desktop computer, a laptop computer, personal digital assistant (PDA), a smart phone or other cellular or mobile phone, or mobile gaming device, among other suitable computing devices. Client devices may execute one or more client applications, such as a web browser (e.g., Microsoft Windows Internet Explorer, Mozilla Firefox, Apple Safari, Google Chrome, and Opera, etc.), or a dedicated application to submit user data, or to make prediction queries over a network 250.

In particular embodiments, each client device may be an electronic device including hardware, software, or embedded logic components or a combination of two or more such components and capable of carrying out the appropriate functions implemented or supported by the client device. For example and without limitation, a client device may be a desktop computer system, a notebook computer system, a netbook computer system, a handheld electronic device, or a mobile telephone. The present disclosure contemplates any client device. A client device may enable a network user at the client device to access the network 250. A client device may enable its user to communicate with other users at other client devices.

A client device may have a web browser, such as MICROSOFT INTERNET EXPLORER, GOOGLE CHROME or MOZILLA FIREFOX, and may have one or more add-ons, plug-ins, or other extensions, such as TOOLBAR or YAHOO TOOLBAR. A client device may enable a user to enter a Uniform Resource Locator (URL) or other address directing the web browser to a server, and the web browser may generate a Hyper Text Transfer Protocol (HTTP) request and communicate the HTTP request to server. The server may accept the HTTP request and communicate to the client device one or more Hyper Text Markup Language (HTML) files responsive to the HTTP request. The client device may render a web page based on the HTML files from server for presentation to the user. The present disclosure contemplates any suitable web page files. As an example and not by way of limitation, web pages may render from HTML files, Extensible Hyper Text Markup Language (XHTML) files, or Extensible Markup Language (XML) files, according to particular needs. Such pages may also execute scripts such as, for example and without limitation, those written in JAVASCRIPT, JAVA, MICROSOFT SILVERLIGHT, combinations of markup language and scripts such as AJAX (Asynchronous JAVASCRIPT and XML), and the like. Herein, reference to a web page encompasses one or more corresponding web page files (which a browser may use to render the web page) and vice versa, where appropriate.

The client device may also include an application that is loaded onto the client device. The client device obtains data from the network 250 and displays it to the user within the application interface.

Exemplary client devices are illustrated in some of the subsequent figures provided herein. This disclosure contemplates any suitable number of client devices, including computing systems taking any suitable physical form. As example and not by way of limitation, computing systems may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, or a combination of two or more of these. Where appropriate, the computing system may include one or more computer systems; be unitary or distributed; span multiple locations; span multiple machines; or reside in a cloud, which may include one or more cloud components in one or more networks. Where appropriate, one or more computing systems may perform without substantial spatial or temporal limitation one or more steps of one or more methods described or illustrated herein. As an example, and not by way of limitation, one or more computing systems may perform in real time or in batch mode one or more steps of one or more methods described or illustrated herein. One or more computing system may perform at different times or at different locations one or more steps of one or more methods described or illustrated herein, where appropriate.

Network cloud 250 generally represents a network or collection of networks (such as the Internet or a corporate intranet, or a combination of both) over which the various components illustrated in FIG. 2 (including other components that may be necessary to execute the system described herein, as would be readily understood to a person of ordinary skill in the art). In particular embodiments, network 250 is an intranet, an extranet, a virtual private network (VPN), a local area network (LAN), a wireless LAN (WLAN), a wide area network (WAN), a metropolitan area network (MAN), a portion of the Internet, or another network 250 or a combination of two or more such networks 250. One or more links connect the systems and databases described herein to the network 250. In particular embodiments, one or more links each includes one or more wired, wireless, or optical links. In particular embodiments, one or more links each includes an intranet, an extranet, a VPN, a LAN, a WLAN, a WAN, a MAN, a portion of the Internet, or another link or a combination of two or more such links. The present disclosure contemplates any suitable network 250, and any suitable link for connecting the various systems and databases described herein.

The network 250 connects the various systems and computing devices described or referenced herein. In particular embodiments, network 250 is an intranet, an extranet, a virtual private network (VPN), a local area network (LAN), a wireless LAN (WLAN), a wide area network (WAN), a metropolitan area network (MAN), a portion of the Internet, or another network 250 or a combination of two or more such networks 250. The present disclosure contemplates any suitable network 250.

One or more links couple one or more systems, engines or devices to the network 250. In particular embodiments, one or more links each includes one or more wired, wireless, or optical links. In particular embodiments, one or more links each includes an intranet, an extranet, a VPN, a LAN, a WLAN, a WAN, a MAN, a portion of the Internet, or another link or a combination of two or more such links. The present disclosure contemplates any suitable links coupling one or more systems, engines or devices to the network 250.

In particular embodiments, each system or engine may be a unitary server or may be a distributed server spanning multiple computers or multiple datacenters. Systems, engines, or modules may be of various types, such as, for example and without limitation, web server, news server, mail server, message server, advertising server, file server, application server, exchange server, database server, or proxy server. In particular embodiments, each system, engine or module may include hardware, software, or embedded logic components or a combination of two or more such components for carrying out the appropriate functionalities implemented or supported by their respective servers. For example, a web server is generally capable of hosting websites containing web pages or particular elements of web pages. More specifically, a web server may host HTML files or other file types, or may dynamically create or constitute files upon a request, and communicate them to clients devices or other devices in response to HTTP or other requests from clients devices or other devices. A mail server is generally capable of providing electronic mail services to various clients devices or other devices. A database server is generally capable of providing an interface for managing data stored in one or more data stores.

In particular embodiments, one or more data storages may be communicatively linked to one or more servers via one or more links. In particular embodiments, data storages may be used to store various types of information. In particular embodiments, the information stored in data storages may be organized according to specific data structures. In particular embodiment, each data storage may be a relational database. Particular embodiments may provide interfaces that enable servers or clients to manage, e.g., retrieve, modify, add, or delete, the information stored in data storage.

The system may also contain other subsystems and databases, which are not illustrated in FIG. 2, but would be readily apparent to a person of ordinary skill in the art. For example, the system may include databases for storing data, storing features, storing outcomes (training sets), and storing models. Other databases and systems may be added or subtracted, as would be readily understood by a person of ordinary skill in the art, without departing from the scope of the invention.

Generally, the techniques disclosed herein may be implemented on hardware or a combination of software and hardware. For example, they may be implemented in an operating system kernel, in a separate user process, in a library package bound into network applications, on a specially constructed machine, on an application-specific integrated circuit (ASIC), or on a network interface card.

Software/hardware hybrid implementations of at least some of the embodiments disclosed herein may be implemented on a programmable network-resident machine (which should be understood to include intermittently connected network-aware machines) selectively activated or reconfigured by a computer program stored in memory. Such network devices may have multiple network interfaces that may be configured or designed to utilize different types of network communication protocols. A general architecture for some of these machines may be described herein in order to illustrate one or more exemplary means by which a given unit of functionality may be implemented. According to specific embodiments, at least some of the features or functionalities of the various embodiments disclosed herein may be implemented on one or more general-purpose computers associated with one or more networks, such as for example an end-user computer system, a client computer, a network server or other server system, a mobile computing device (e.g., tablet computing device, mobile phone, smartphone, laptop, or other appropriate computing device), a consumer electronic device, a music player, or any other suitable electronic device, router, switch, or other suitable device, or any combination thereof. In at least some embodiments, at least some of the features or functionalities of the various embodiments disclosed herein may be implemented in one or more virtualized computing environments (e.g., network computing clouds, virtual machines hosted on one or more physical computing machines, or other appropriate virtual environments).

FIG. 3 illustrates an exemplary embodiment of object placement verification system 220 according to an embodiment. It should be known that the various components described herein are exemplary and for illustration purposes only. In this example, object placement verification system 220 includes document data interface 302, sensor data interface 304, object recognition component 306, data transformation component 308, comparator 312, dynamic threshold component 314, and discrepancy component 316. The object placement verification system 220 may also include one or more data stores, including, for example, sensor data store 330, document data store 332, compliance data store 334, report data store 336.

It should be noted that although the data stores are shown as separate data stores, data from the data stores can be maintained across fewer or additional data stores. The data stores can be accessed by each of the various components in order to perform the functionality of the corresponding component. Other components, systems, services, etc. may access the data stores. Although object placement verification system 220 is shown as a single system, the system may be hosted on multiple server computers and/or distributed across multiple systems. Additionally, the components may be performed by any number of different computers and/or systems. Thus, the components may be separated into multiple services and/or over multiple disparate systems to perform the functionality described herein.

Document data interface 302 is operable to obtain construction site data through an appropriate interface. Document data interface 302 may include a data interface and service interface configured to periodically receive documents, requests, and/or any other relevant information to facilitate object placement verification. In an example, a database server or other appropriate component is generally capable of providing an interface for managing data stored in one or more data stores. In an embodiment, document data interface 302 can include any appropriate components known or used to receive requests or other data from across a network, such as may include one or more application programming interfaces (APIs) or other such interfaces for receiving such requests and/or data, including but not limited to, data scrapes, API access, etc. In a specific example, document data interface 302 communicates with user devices, document data store 332, or other repositories or devices to obtain document data.

Obtaining construction site data can include receiving data that includes representations of construction sites. In certain embodiments, the data can further include compliance data, regulatory data, etc. The data can be obtained from a building company, a development company, a draftsperson, a government agency, or from any other source of such data. The data may be obtained via download, API access, wirelessly, etc.

Construction site data can include design plans associated with the construction site, a representation one or more objects at the construction site, a representation of the physical environment such as the terrain, a representation of a reference marker, and the like. The objects can include items typically found at a construction site, including for example, structural beams, floors, flooring, walls, plumbing, electrical wiring, fire sprinklers, door frames and doors, landscaping, walkways, buildings, building foundations, construction equipment, construction tools, etc. The reference marker can include physical objects, physical markings, non-physical markings including those using lasers, LiDAR, sound, geo-tagging, and the like. In an embodiment, the marker includes a two-dimensional marker (e.g., a pattern of shapes, a quick response (QR) code, etc.) In an embodiment, a marker can be associated with additional data such as dimension data, pose data, and the like.

In an embodiment, the design plans can include computer-aided design (CAD) data, imaging data, and/or data in other file formats. In an embodiment, the CAD data can specify the physical properties (e.g., dimensions) of one or more objects, the physical environment, reference markers, etc. For example, the construction site data can include metadata. The metadata can include additional information about the construction site, including, for example, information about objects at the construction site such as geographic location of the objects, dimensions of objects, sizes of the objects, tags indicating the front, top, or rear of an object, distances between objects, tags indicated a type of object, the layout of the construction site including object locations, a predetermined pose of an object (e.g., the location and position of the object based on a marker and/or the direction of little g), physical environment information such as elevation information, land information, etc.

In various embodiments, the additional information can be stored in document data store 332. The additional information may be manually provided. For example, in some embodiments, a user may be prompted to enter the additional information. Still in other embodiments, the additional information is computer generated. In such as case, the additional information may be uploaded to document data store 332.

Sensor data interface 304 is operable to obtain sensor data through an appropriate interface from an appropriate sensor capture device. Examples of sensors include a LIDAR device, an imaging device (e.g., a camera, a video camera, a mobile device, etc.—examples of mobile devices include a smartphone, a portable media device, a tablet computer, a laptop computer, a wearable device, etc.), a sonar device, a radar device, a reflectivity measuring device, a sound measuring device, a density measuring device, a depth sensor, among others. The sensor data can be obtained from an unmanned aerial vehicle (UVA), satellite, airplane, etc. The sensor data can include two-dimensional imaging data, three-dimensional point data, RFID, radar data, depth data, GPS data, infrared, light coding, etc. The sensor data may be obtained via download, API access, wirelessly, etc.

Sensor data interface 304 may include a data interface and a service interface configured to periodically receive sensor data and other relevant information (e.g., depth information, GPS information, etc.) to facilitate object placement verification and display such information. In an embodiment, a database server or other appropriate component is generally capable of providing an interface for managing data stored in one or more data stores. In an embodiment, sensor data interface 304 can include any appropriate components known or used to receive requests or other data from across a network, such as may include one or more application programming interfaces (APIs) or other such interfaces for receiving such requests and/or data, including but not limited to, data scrapes, API access, etc. In a specific example, sensor data interface 304 communicates with sensors, sensor data store 330, or other repositories or devices to obtain sensor data.

Object recognition component 306 is operable to analyze the sensor data using one or more object recognition models one or more physical objects and markers represented in the sensor data. In an example, the object recognition models can be used to analyze imaging data to recognize one or more objects and/or markers. The recognition models can be stored in model data store 338. In accordance an embodiment, the one or more models can be used to recognize a type of object. In an embodiment, there may be a plurality of models, each model trained for a different type of object. In a specific example, the object recognition algorithm can be trained to recognize pipe sleeves. In another example, the object recognition can be used to recognize one or more markers.

The object recognition component 306 can generate an object recognition score that quantifies a degree of similarity between a query object and a plurality of candidate objects. Object recognition component 306 can utilize, for example, a convolution neural network (CNN), support vector machine SVM detection algorithm, or other learning model to recognize an object. For example, an image of an object can be received. The image can be evaluated by object recognition component 306 to attempt to match the image of the object to a stored image of objects, where each potential match can be associated with an object identification confidence score. The object associated with, for example, a highest score can be selected as the object.

In various embodiments, object recognition component 306 can be used to recognize markers represented in the sensor data. Similarly to described above, an image of a marker can be received. The image can be evaluated by object recognition component 306 to attempt to match the image of the marker to a stored image of markers, where each potential match can be associated with an object identification confidence score. The marker associated with, for example, a highest score can be selected as the marker.

Once one or more markers are recognized in the sensor data, data transformation component 308 can use an image processing technique to transform or map the sensor data and the construction site data to a common coordinate system based on corresponding markers from the sensor data and the construction site data. In an embodiment, this can include mapping the sensor data to the construction site data. This allows for matching points between the sensor data and the construction site data. For example, points and/or features for a marker represented in the sensor data can be mapped to points and/or features for a corresponding marker represented in the construction site data. Said another way, given sensor data of the physical environment, and construction site data of the physical environment, a set of points in the sensor data can be identified as the same points in the construction site data. Continuing with this example, points or features in the sensor data can be matched with the corresponding points or corresponding features in the construction site data. In an example, the set of points or features in the sensor data can correspond to the marker represented in the sensor data and the corresponding points or corresponding features in the construction site data can correspond to the marker represented in the construction site data.

In an embodiment, the image processing technique can include an image registration technique, an image alignment technique, image rectification technique, or other such technique to match points or features in the sensor data with corresponding points or corresponding features in the construction site data. In general, one of the sensor data or the construction site data is referred to as the source and the other data is referred to as the target. Image registration involves spatially transforming the source data (e.g., sensor data) to align with the target data. In an embodiment, the reference frame or reference marker in the target data (e.g., construction site data) is stationary, while the other datasets are transformed to match to the target. Intensity-based methods compare intensity patterns in data sets via correlation metrics, while feature-based methods find correspondence between data set features such as points, lines, and contours. Intensity-based methods register entire data sets or sub-data sets. If sub-data sets are registered, centers of corresponding sub data sets are treated as corresponding feature points. Feature-based methods establish a correspondence between a number of especially distinct points in data sets. Knowing the correspondence between a number of points in data sets, a geometrical transformation is then determined to map the target data to the reference data, thereby establishing point-by-point correspondence between the reference and target data.

In another embodiment, image processing techniques can include transformation models or rectifying models such as rotation, scaling, translation, and other affine transforms to match points or features in the sensor data with corresponding points or corresponding features in the construction site data to reduce misalignment or otherwise align the sensor data and the construction site data.

In yet another embodiment, image processing techniques can include spatial and frequency domain techniques to match points or features in the sensor data with corresponding points or corresponding features in the construction site data. In an embodiment, spatial techniques operate in the image domain, matching intensity patterns or features in images. Some of the feature matching algorithms are outgrowths of traditional techniques for performing manual image registration, in which an operator chooses corresponding control points (CP) in images. When the number of control points exceeds the minimum required to define the appropriate transformation model, iterative algorithms like RANSAC can be used to robustly estimate the parameters of a particular transformation type (e.g. affine) for registration of the images. Frequency-domain methods find the transformation parameters for registration of the images while working in the transform domain. Applying the phase correlation method to a pair of images produces a third image which contains a single peak. The location of this peak corresponds to the relative translation between the images. Unlike many spatial-domain algorithms, the phase correlation method is resilient to noise, occlusions, and other defects typical of medical or satellite images. Additionally, the phase correlation uses the fast Fourier transform to compute the cross-correlation between the two images, generally resulting in large performance gains. The method can be extended to determine rotation and scaling differences between two images by first converting the images to log-polar coordinates. Due to properties of the Fourier transform, the rotation and scaling parameters can be determined in a manner invariant to translation.

In yet another embodiment, image processing techniques can include manual, interactive, semi-automatic techniques to match points or features in the sensor data with corresponding points or corresponding features in the construction site data. Manual methods can provide tools to align the images manually. Interactive methods perform certain key operations automatically while still relying on the user to guide the registration. Semi-automatic methods perform more of the registration steps automatically but depend on the user to verify the correctness of a registration. Automatic methods perform all registration steps automatically.

Comparator 312 can then determine the similarity or correspondence between objects (e.g., pipe sleeve) represented in the sensor data with corresponding objects represented in the construction site data. Said another way, comparator 312 can execute a spatial verification technique or other such technique in which a location of an object represented in the sensor data is compared to a location of a corresponding object represented in the construction site data to determine an offset or discrepancy between object locations. For example, once the sensor data is aligned or otherwise mapped to the construction site data based on corresponding markers represented in the sensor data and the construction site data, the correspondence between a pipe sleeve represented in the sensor data and a corresponding pipe sleeve represented in the construction site data can be determined. This can include, for example, determining where the pipe sleeve represented in the sensor data overlaps the pipe sleeve represented in the construction site data. This can further include determining how far off (e.g., the offset or discrepancy) between the pipe sleeve represented in the sensor data is from the pipe sleeve represented in the construction site data. In an embodiment, the offset or discrepancy can correspond to a physical distance, including, for example, a physical offset.

In certain embodiments, a manual approach may be utilized to compare the similarity between objects represented in the sensor data with corresponding objects represented in the construction site data. In an example, once the sensor data is aligned and overlaid on the construction site data in accordance with embodiments described herein and techniques known in the art, a distance measure tool can be used to measure any offset between objects represented in the sensor data with corresponding objects represented in the construction site data. In an embodiment, the distance measure tool may be part of a software package, add on software component, etc.

The offset can then be used to determine whether an object (e.g., pipe sleeve) represented in the sensor data is correctly positioned. For example, once spatio-temporal differences or an offset between the object represented in the sensor data and the corresponding object represented in the construction site data is determined, discrepancy component 316 is operable to compare the offset to a threshold. Based on the comparison, discrepancy component 316 is configured to classify the object. For example, in the situation the offset fails to satisfy the threshold, the object represented in the sensor data may not be in the correct location and may labeled as “incorrectly located”. In various embodiments, a report indicating the discrepancy may be generated. In the situation the offset satisfies the threshold, the object represented in the image may be located in the correct location and labeled as “correctly located.” A variety of other labels and/or label types, which may assist an object placement verification system, reporting system, training system, etc., may be provided and used without departing from the scope of the invention.

In an embodiment, dynamic threshold component 314 is operable to set the threshold used to determine a discrepancy. In an embodiment, dynamic threshold component 314 can set a static or a dynamic threshold. In an embodiment, the threshold may be manually adjusted by a user, or automatically adjusted in accordance with a compliance policy, regulations, building codes, or another such standard or preference stored in compliance data store 334. For example, dynamic threshold component 314 can analyze compliance data and set the threshold based on the compliance data. In some embodiments, the threshold can correspond to a distance. For example, the threshold may be set to ⅛ of an inch. In some embodiments, the threshold is input by the design team or by other methods as annotations on the objects of the design plans. For example, a pipe may have an accuracy tolerance of ⅛ of an inch, and that tolerance may be added as an annotation on the pipe via a CAD application used to create design plan data.

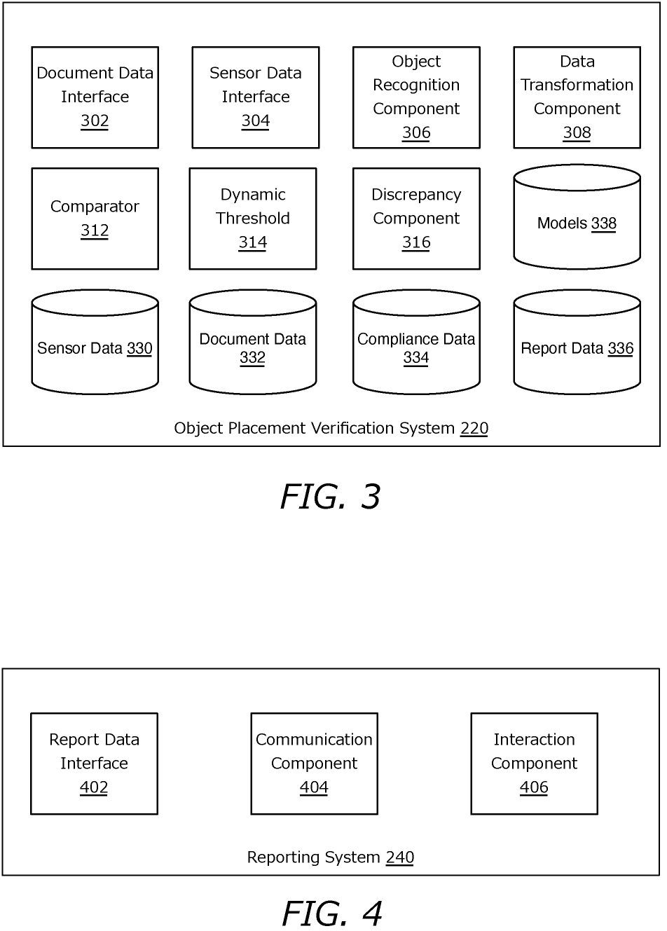

In certain embodiments, a report indicating such information may be generated. FIG. 4 illustrates an exemplary reporting system in accordance with various embodiments. In this example, reporting system 240 includes report data interface 402, communication component 404, and interaction component 406. Although reporting system 240 is shown as a single system, the system may be hosted on multiple server computers and/or distributed across multiple systems. Additionally, the components may be performed by any number of different computers and/or systems. Thus, the components may be separated into multiple services and/or over multiple disparate systems to perform the functionality described herein.

Report data interface 402 is operable to obtain reporting data through an appropriate interface. In an embodiment, the reporting data includes information to inform a user that a location of an object represented in sensor data is different from the location of the corresponding object represented in the construction site data. In an embodiment, the report may indicate the discrepancy. For example, the report may highlight, emphasis text, add text or graphics, etc., to indicate any discrepancies. The report may identify objects for review. In an embodiment, the report may provide a reason and/or solution for the discrepancy.

Report data interface 402 may include a data interface and service interface configured to periodically receive report data, requests, and/or any other relevant information to facilitate reporting for object placement verification. In an example, a database server or other appropriate component is generally capable of providing an interface for managing data stored in one or more data stores. In an embodiment, report data interface 402 can include any appropriate components known or used to receive requests or other data from across a network, such as may include one or more application programming interfaces (APIs) or other such interfaces for receiving such requests and/or data, including but not limited to, data scrapes, API access, etc. In a specific example, report data interface 402 communicates with user devices, report data store 336, or other repositories or devices to obtain reporting data.

Communication component 404 is operable process the reporting data to provide reports and/or notifications to a user or other authorized entity, and/or accounts. The reports and/or notifications may be presented to a user via a computing device such as a content server or another appropriate computing device.

The reports may be obtained from report data store 336. In an embodiment, the reports may comprise data files including the appropriate information describing any discrepancies between objects represented in the sensor data and objects in the construction site data. In another embodiment, a link may be provided to access the reports. In yet another example, communication component 404 may generate a graphical user interface to present the reports to permit authorized users to quickly and efficiently view and interact with the reports.

In an embodiment, the graphical user interface may include information to assist a user in locating any discrepancies and understanding any discrepancies. For example, the graphical user interface may include an overlay of the construction site on a map and graphical elements that emphasize the discrepancies and/or a location of the discrepancies. The graphical elements may include color, shapes, graphics, icons, tags, etc. In should be noted that although a graphical user interface is described herein as being provided, however, other types of communication may be provided without departing from the scope of the invention, including, but not limited to: written material such as code, instruction snippets, one or more two and/or three-dimensional images, video, audio/oral instructions, etc.

Interaction component 406 may provider user selectable elements the enable a user to interact with the interface, display information about the discrepancy, trigger outside applications such as a navigation or mapping application, etc. For example, in some embodiments, the interface may include a widget (e.g., graphical button) that allows a user to preview at least information about any discrepancies. For instance, an interface view may have a button that allows the user to view one or more discrepancies based on type of discrepancy. Still in other embodiments, interaction component 406 may interact with a navigation or mapping application to help a user navigate to one or more locations associated with a discrepancy. In another example, interaction component 406 may provide instructions to a remote application to assist with such navigation.

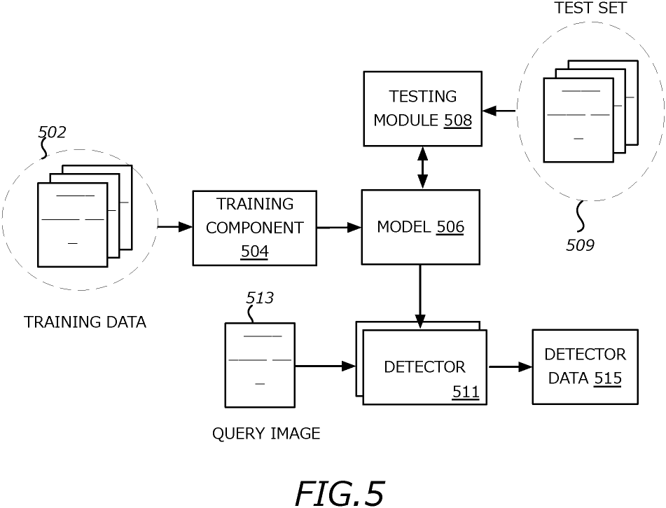

FIG. 5 illustrates an exemplary embodiment of training system 230 in accordance with an embodiment. In this example, training data including a set of image 502 is obtained that can be used to train one or more models (e.g., SVM models, neural networks) 506 or other machine learning-based algorithms to recognize objects represented in sensor data. The imaging data can include, for example, an image of an object, such as a pipe sleeve. It should be noted that the objects are not limited to pipe sleeves, and the objects may include other types of objects typically found at a construction site, including for example, structural beams, floors, flooring, walls, plumbing, electrical wiring, fire sprinklers, door frames and doors, landscaping, walkways, buildings, building foundations, construction equipment, construction tools, etc. The imaging data can come from one or more sources, such as from the Internet, image capture devices, data storage devices, and the like. users including, for example, companies, vendors, and the like.

In order to function as training data for the models, at least some of the images will include (or be associated with) data that indicates a type or classification for the object represented in each image. For example, set of images 502 may comprise labelled imaging data. Labelled imaging data can include imaging data associated with metadata or other data that specifies a type of object. The classifications in at least some embodiments will be selected from a set of classifications, or sub-classifications, used to identify various objects.

In some embodiments the set of images will be analyzed to determine which images include data sufficient to identify an object associated with the object represented in each of the images, and those images can be considered a training set to be used to train a model. In at least some embodiments there is one model trained for each type of object, with multiple types of classifications of that type of object being possible outcomes from the network. In some embodiments, a portion of the training set will be retained as a testing set 509 to use to test the accuracy of the trained model. In this example, the training images are accessible to a training component 504 which can feed the images to model 506 in order to train the model. As mentioned, the image and classification data will be fed to the model so the model can learn features of objects associated with different classifications of objects. The network can then learn various combinations or relations of features for different classifications, such that when a query image is processed with the trained model the model can recognize the features and output the appropriate classification, although various other approaches can be utilized as well within the scope of the various embodiments.

In some embodiments the training images 502 are to be used as training data for a SVM algorithm or other learning model such as a convolution neural network (CNN). As mentioned, the images can be classified, either when provided or through a classification analysis, to determine a primary classification, such as a particular object. Various other images provided by third party sources can be used for training as well as discussed and suggested elsewhere herein. The SVM can be trained using some or all of the designated training data. Once at least the initial training has completed, a testing module 508 can utilize the testing images 509 to test the trained SVM. Since the testing images already include classification data, the classifications generated by the SVM can be compared against that data to determine the accuracy of the SVM, both overall and for different types of documents. The testing images can also be used to further train the SVM. The results can be analyzed and if the results are acceptable, such as where the accuracy at least meets a minimum accuracy threshold for some or all of the classifications, the SVM can be provided to a detector 511, e.g., an object detector, that is able to accept query images 513 from various sources, such as image capture devices, user, etc., and generate classification data including object detection data that includes classifications 515 for objects represented in those images. As mentioned herein, such an approach can be used for a number of different purposes, including, for example, object placement verification.

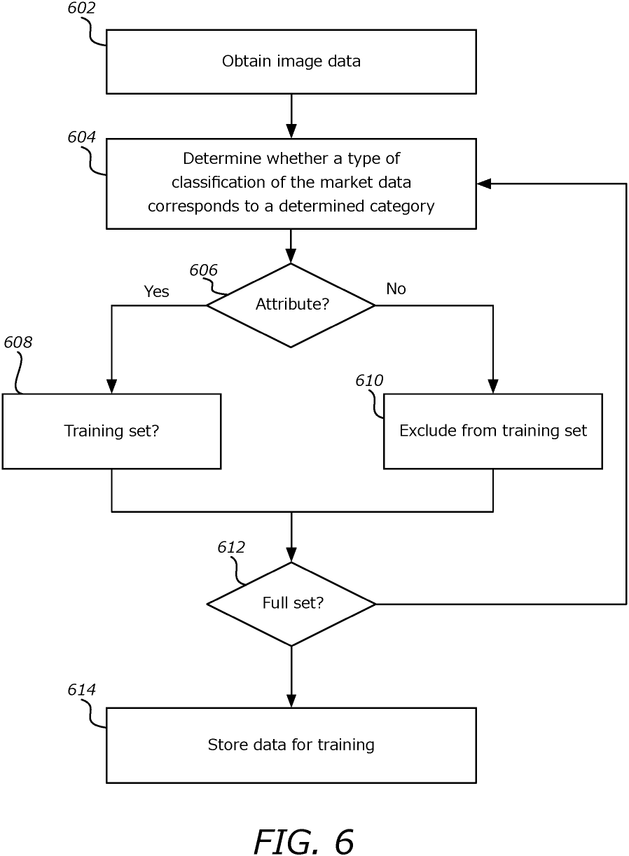

FIG. 6 illustrates an example process for determining training data that can be utilized in accordance with various embodiments. It should be understood that, for any process discussed herein, there can be additional, fewer, or alternative steps, performed in similar or different orders, or in parallel, within the scope of the various embodiments unless otherwise stated. In this example, image data can be obtained 602 for analysis. The image data can include representations of objects. The objects can include items typically found at a construction site, including for example structural beams, floors, flooring, walls, plumbing, electrical wiring, fire sprinklers, door frames and doors, landscaping, walkways, buildings, building foundations, construction equipment, construction tools, etc. In certain embodiments, the objects can include reference markers. The image data can be obtained from an unmanned aerial vehicle (UVA), satellite, airplane, or another image capture device. In certain embodiments, the image data can be from one or more data stores maintained directly or indirectly by a content provider, resource provider, or a third-party, or from multiple sources, among other such options. The image data can include 2D or 3D image data, among others, and can be used as a reference for training the model.

An object type associated with each image (or other information associated with each image) can be used to determine 604 whether a type of classification of the image corresponds to a category and includes particular attributes, or types of attributes, for which a model (e.g., logistic regression, neural network, or another machine learning algorithm) can be trained. As described, the different object types, can include, for example, pipe sleeves, walls, stairs, etc.

If it is determined 606 that an image exhibits the attribute for a particular category, then that image can be added 608 to the training set. For example, the training set can include a set of images for pipe sleeves. In another example, the training set can include a set of images for walls. An image can include a label or tag, where each label provides a reference identification of an object. For example, the image data can include data associated with an object, such as a pipe sleeve. The image data includes data from which physical properties associated with an object can be determined, such as architectural drawing data of a pipe sleeve from which physical dimensions of the pipe sleeve, the material of the pipe sleeve, the thickness of the material of the pipe sleeve, etc., can be determined. The image data can additionally include data that identifies the object, such as a label associated with the pipe sleeve data that identifies the pipe sleeve (e.g., pipe sleeve XYZ from vendor ABC).

If not, that image can be excluded 610 from the training set. As mentioned elsewhere herein, in at least some embodiments, some of the images may be instead added to a testing set or not added to any set but may have the attribute classification associated therewith.

If it is determined 612 that a full training set has been obtained, using any appropriate criterion as discussed or suggested herein, such as a threshold number of images, then the training set generation can complete, and the images can be stored 614 for training and other purposes. Otherwise, the process can continue until a full set is obtained, all of the relevant image data is analyzed, or another stop condition is satisfied.

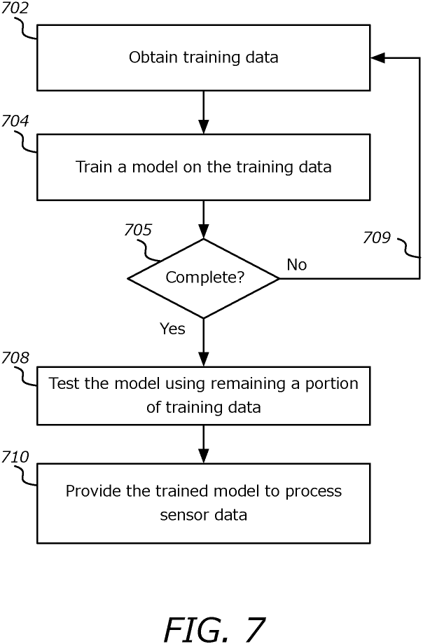

FIG. 7 illustrates an example process for training a model that can be utilized in accordance with various embodiments. Once the training data is obtained 702, the training data can be provided as input to a model training process. The training data can include, for example, representations of objects. The objects can include items typically found at a construction site, including for example structural beams, floors, flooring, walls, plumbing, electrical wiring, fire sprinklers, door frames and doors, landscaping, walkways, buildings, building foundations, construction equipment, construction tools, etc. In certain embodiments, the objects can include reference markers.

In the example of a neural network, or other machine learning-based model, the model can be trained 704 on the training data to learn various combinations or relations of features of the images, such that when an image is processed with the trained model, the model can recognize the features and output classification, although various other outputs can be utilized as well within the scope of the various embodiments. If it is determined 705 that a stop condition has been met so that training should be completed, such as by processing the entire training set, then the trained model can be provided to process image data to identify one or more objects and/or reference markers. As discussed herein, the model might first go through a process to test 708 using at least some of the training classified with the attribute type from earlier steps of the process. If the training is not complete, then the training process can continue 709 until a trained model is obtained. Thereafter, the trained model can be provided 710 to process imaging data to identify objects represented to that data.

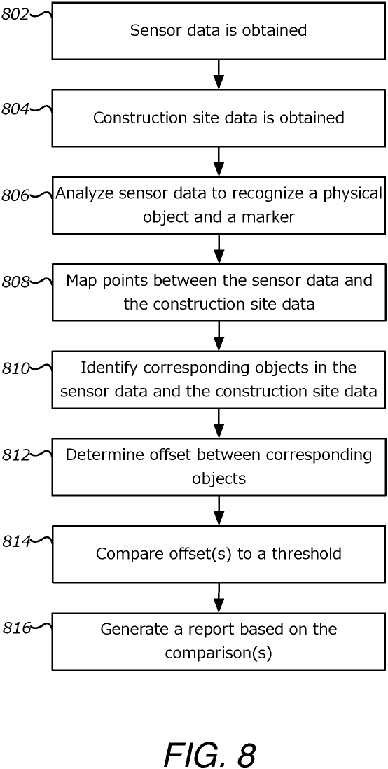

FIG. 8 illustrates an exemplary process for verifying object placement in accordance with various embodiments. It should be understood that, for any process discussed herein, there can be additional, fewer, or alternative steps performed in similar or different orders, or in parallel, within the scope of the various embodiments unless otherwise stated. In this example, sensor data that includes a representation of a physical environment is obtained 802. The sensor data can be obtained from an unmanned aerial vehicle (UVA), satellite, airplane, etc. The sensor data can include two-dimensional data, three-dimensional point data, RFID, radar data, etc. The physical environment can include a construction site. It should be noted, however, that the physical environment can include any number of different locations.

The construction site can include one or more objects, markers, etc. The objects can include items typically found at a construction site, including for example, structural beams, floors, flooring, walls, plumbing, electrical wiring, fire sprinklers, door frames and doors, landscaping, walkways, buildings, building foundations, construction equipment, construction tools, etc. The markers can include physical objects, physical markings, non-physical markings including those using lasers, LiDAR, sound, geo-tagging, and the like. The markers can be associated with dimensions. For example, the length, width, and height of the marker is known. The markers can be associated with GPS coordinates or other position coordinates that can be used to identify a geographic location of the maker.

Construction site data can be obtained 804. The construction site data can include design plans associated with the construction site, a representation of an object, and a representation of a reference marker. In an embodiment, the design plans can include the construction site data including, for example computer-aided design (CAD) data. In an embodiment, the CAD data can specify the physical properties (e.g., dimensions, location) of the object.

The sensor data can be analyzed 806 using at least one object recognition algorithms that utilize various models to recognize a physical object and a marker. In a specific example, the object recognition algorithm can be trained to recognize pipe sleeves. In the situation an object and/or marker cannot be identified, the identification of some or all of the unidentified or ambiguous objects and/or markers is done by a human. In accordance an embodiment, a model can be trained to recognize a type of object. In an embodiment, there may be a plurality of object recognition algorithms, each algorithm trained for a different type of object. In certain embodiments, the object recognition algorithm can be trained for a plurality of different types of objects. In a specific example, the object recognition algorithm can be trained to recognize pipes. In another example, the object recognition can be used to recognize one or more markers. In various embodiments, the model is a convolution neural network or other such machine learned based model.

In an embodiment, an image processing technique can be utilized to transform the sensor data and the construction site data to a common coordinate system. This allows for mapping 808 points between the sensor data and the construction site data. Said another way, given sensor data of the physical environment, and construction site data of the physical environment, a set of points in the sensor data can be identified as well as the corresponding set of in the construction site data. In an example, the set of points or features in the sensor data can correspond to the marker represented in the sensor data and the corresponding points or corresponding features in the construction site data can correspond to the marker represented in the construction site data. The image processing technique can determine an alignment of the two data sets, such as by matching reference markers and determining an alignment that causes the references markers to be aligned. Said another way, points or features in the sensor data can be mapped to corresponding points or corresponding features in the construction site data.

Corresponding objects in the sensor data and the construction site data are identified 810. In an example, a pipe sleeve at a particular location with certain dimensions is identified in the sensor data and a corresponding pipe sleeve at the same particular location with the same certain dimensions is identified in the construction site data. In an embodiment, a determination is made that the two pipe sleeves are sufficiently similar to indicate a high likelihood of being corresponding pipe sleeves.

The similarity or correspondence or offset between object (e.g., pipe sleeve) represented in the sensor data and the corresponding object represented in the construction site data is determined 812. In an example, a location of pipe sleeve represented in the sensor data is compared to a location of the corresponding pipe sleeve represented in the construction site data to determine an offset or discrepancy between object locations. In an embodiment, the offset or discrepancy can correspond to a physical discrepancy. Examples of physical discrepancies include an object or structure under construction component being located at a different location as compared to its corresponding object or structure, being of an different dimension as compared to its corresponding object or structure, being of a different color as compared to its corresponding object or structure, being comprised of a different material as compared to its corresponding object or structure, having a different surface texture as compared to its corresponding object or structure, etc.

The offset(s) can be compared 814 to a threshold. In some embodiments, the threshold can correspond to a distance. For example, the threshold may be set to ⅛ of an inch. Based on the comparison, the object is labelled 816. For example, in the situation the offset fails to satisfy the threshold, the object represented in the sensor data may not be in the correct location and labeled as “incorrectly located.” In the situation the offset satisfies the threshold, the object represented in the image may be in the correct location and labelled as “correctly located.”

A report based on the labels can be generated 618 and provided to appropriate users. For example, the report may indicate any discrepancies between objects represented in the sensor data and corresponding objects represented in the construction site data. For example, the report may highlight, emphasis text, add text or graphics, etc., to indicate any discrepancies. The report may identify objects for review. In an embodiment, the report may provide a reason and/or solution for the discrepancy.

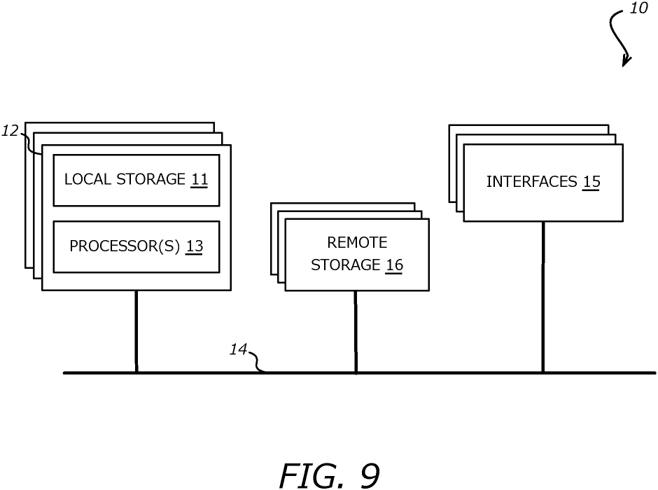

Referring now to FIG. 9, there is shown a block diagram depicting an exemplary computing device 10 suitable for implementing at least a portion of the features or functionalities disclosed herein. Computing device 10 may be, for example, any one of the computing machines listed in the previous paragraph, or indeed any other electronic device capable of executing software- or hardware-based instructions according to one or more programs stored in memory. Computing device 10 may be configured to communicate with a plurality of other computing devices, such as clients or servers, over communications networks such as a wide area network a metropolitan area network, a local area network, a wireless network, the Internet, or any other network, using known protocols for such communication, whether wireless or wired.

In one aspect, computing device 10 includes one or more central processing units (CPU) 12, one or more interfaces 15, and one or more busses 14 (such as a peripheral component interconnect (PCI) bus). When acting under the control of appropriate software or firmware, CPU 12 may be responsible for implementing specific functions associated with the functions of a specifically configured computing device or machine. For example, in at least one aspect, a computing device 10 may be configured or designed to function as a server system utilizing CPU 12, local memory 11 and/or remote memory 16, and interface(s) 15. In at least one aspect, CPU 12 may be caused to perform one or more of the different types of functions and/or operations under the control of software modules or components, which for example, may include an operating system and any appropriate applications software, drivers, and the like.

CPU 12 may include one or more processors 13 such as, for example, a processor from one of the Intel, ARM, Qualcomm, and AMD families of microprocessors. In some embodiments, processors 13 may include specially designed hardware such as application-specific integrated circuits (ASICs), electrically erasable programmable read-only memories (EEPROMs), field-programmable gate arrays (FPGAs), and so forth, for controlling operations of computing device 10. In a particular aspect, a local memory 11 (such as non-volatile random-access memory (RAM) and/or read-only memory (ROM), including for example one or more levels of cached memory) may also form part of CPU 12. However, there are many different ways in which memory may be coupled to system 10. Memory 11 may be used for a variety of purposes such as, for example, caching and/or storing data, programming instructions, and the like. It should be further appreciated that CPU 12 may be one of a variety of system-on-a-chip (SOC) type hardware that may include additional hardware such as memory or graphics processing chips, such as a QUALCOMM SNAPDRAGON® or SAMSUNG EXYNOS® CPU as are becoming increasingly common in the art, such as for use in mobile devices or integrated devices.

As used herein, the term “processor” is not limited merely to those integrated circuits referred to in the art as a processor, a mobile processor, or a microprocessor, but broadly refers to a microcontroller, a microcomputer, a programmable logic controller, an application-specific integrated circuit, and any other programmable circuit.

In one aspect, interfaces 15 are provided as network interface cards (NICs). Generally, NICs control the sending and receiving of data packets over a computer network; other types of interfaces 15 may for example support other peripherals used with computing device 10. Among the interfaces that may be provided are Ethernet interfaces, frame relay interfaces, cable interfaces, DSL interfaces, token ring interfaces, graphics interfaces, and the like. In addition, various types of interfaces may be provided such as, for example, universal serial bus (USB), Serial, Ethernet, FIREWIRE®, THUNDERBOLT®, PCI, parallel, radio frequency (RF), BLUETOOTH®, near-field communications (e.g., using near-field magnetics), 802.11 (WiFi), frame relay, TCP/IP, ISDN, fast Ethernet interfaces, Gigabit Ethernet interfaces, Serial ATA (SATA) or external SATA (ESATA) interfaces, high-definition multimedia interface (HDMI), digital visual interface (DVI), analog or digital audio interfaces, asynchronous transfer mode (ATM) interfaces, high-speed serial interface (HSSI) interfaces, Point of Sale (POS) interfaces, fiber data distributed interfaces (FDDIs), and the like. Generally, such interfaces 15 may include physical ports appropriate for communication with appropriate media. In some cases, they may also include an independent processor (such as a dedicated audio or video processor, as is common in the art for high-fidelity A/V hardware interfaces) and, in some instances, volatile and/or non-volatile memory (e.g., RAM).

Although the system shown in FIG. 9 illustrates one specific architecture for a computing device 10 for implementing one or more of the embodiments described herein, it is by no means the only device architecture on which at least a portion of the features and techniques described herein may be implemented. For example, architectures having one or any number of processors 13 may be used, and such processors 13 may be present in a single device or distributed among any number of devices. In one aspect, single processor 13 handles communications as well as routing computations, while in other embodiments a separate dedicated communications processor may be provided. In various embodiments, different types of features or functionalities may be implemented in a system according to the aspect that includes a client device (such as a tablet device or smartphone running client software) and server systems (such as a server system described in more detail below).

Regardless of network device configuration, the system of an aspect may employ one or more memories or memory modules (such as, for example, remote memory block 16 and local memory 11) configured to store data, program instructions for the general-purpose network operations, or other information relating to the functionality of the embodiments described herein (or any combinations of the above). Program instructions may control execution of or comprise an operating system and/or one or more applications, for example. Memory 16 or memories 11, 16 may also be configured to store data structures, configuration data, encryption data, historical system operations information, or any other specific or generic non-program information described herein.

Because such information and program instructions may be employed to implement one or more systems or methods described herein, at least some network device embodiments may include non-transitory machine-readable storage media, which, for example, may be configured or designed to store program instructions, state information, and the like for performing various operations described herein. Examples of such non-transitory machine- readable storage media include, but are not limited to, magnetic media such as hard disks, floppy disks, and magnetic tape; optical media such as CD-ROM disks; magneto-optical media such as optical disks, and hardware devices that are specially configured to store and perform program instructions, such as read-only memory devices (ROM), flash memory (as is common in mobile devices and integrated systems), solid state drives (SSD) and “hybrid SSD” storage drives that may combine physical components of solid state and hard disk drives in a single hardware device (as are becoming increasingly common in the art with regard to personal computers), memory storage, random access memory (RAM), and the like. It should be appreciated that such storage means may be integral and non-removable (such as RAM hardware modules that may be soldered onto a motherboard or otherwise integrated into an electronic device), or they may be removable such as swappable flash memory modules (such as “thumb drives” or other removable media designed for rapidly exchanging physical storage devices), “hot-swappable” hard disk drives or solid state drives, removable optical storage discs, or other such removable media, and that such integral and removable storage media may be utilized interchangeably. Examples of program instructions include both object code, such as may be produced by a compiler, machine code, such as may be produced by an assembler or a linker, byte code, such as may be generated by for example a JAVA® compiler and may be executed using a Java virtual machine or equivalent, or files containing higher level code that may be executed by the computer using an interpreter (for example, scripts written in Python, Perl, Ruby, Groovy, or any other scripting language).

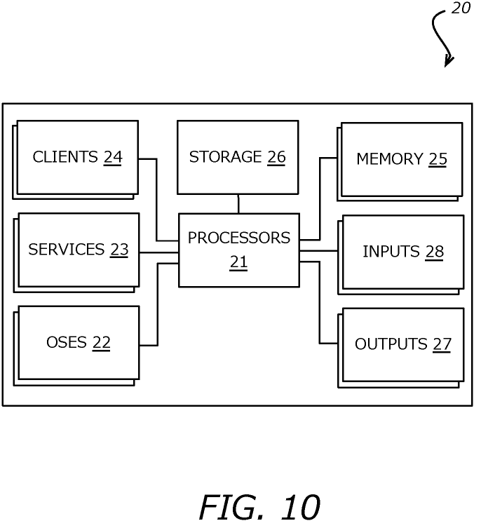

In some embodiments, systems may be implemented on a standalone computing system. Referring now to FIG. 10, there is shown a block diagram depicting a typical exemplary architecture of one or more embodiments or components thereof on a standalone computing system. Computing device 20 includes processors 21 that may run software that carry out one or more functions or applications of embodiments, such as for example a client application 24. Processors 21 may carry out computing instructions under control of an operating system 22 such as, for example, a version of MICROSOFT WINDOWS® operating system, APPLE macOS® or iOS® operating systems, some variety of the Linux operating system, ANDROID® operating system, or the like. In many cases, one or more shared services 23 may be operable in system 20, and may be useful for providing common services to client applications 24. Services 23 may for example be WINDOWS® services, user-space common services in a Linux environment, or any other type of common service architecture used with operating system 22. Input devices 28 may be of any type suitable for receiving user input, including for example a keyboard, touchscreen, microphone (for example, for voice input), mouse, touchpad, trackball, or any combination thereof. Output devices 27 may be of any type suitable for providing output to one or more users, whether remote or local to system 20, and may include for example one or more screens for visual output, speakers, printers, or any combination thereof. Memory 25 may be random-access memory having any structure and architecture known in the art, for use by processors 21, for example to run software. Storage devices 26 may be any magnetic, optical, mechanical, memory storage, or electrical storage device for storage of data in digital form (such as those described above, referring to FIG. 9). Examples of storage devices 26 include flash memory, magnetic hard drive, CD-ROM, and/or the like.

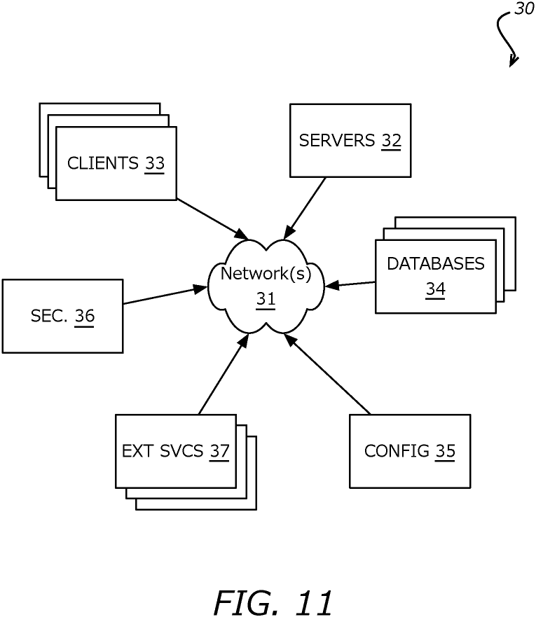

In some embodiments, systems may be implemented on a distributed computing network, such as one having any number of clients and/or servers. Referring now to FIG. 11, there is shown a block diagram depicting an exemplary architecture 30 for implementing at least a portion of a system according to one aspect on a distributed computing network. According to the aspect, any number of clients 33 may be provided. Each client 33 may run software for implementing client-side portions of a system; clients may comprise a standalone computing system 20 such as that illustrated in FIG. 10. In addition, any number of servers 32 may be provided for handling requests received from one or more clients 33. Clients 33 and servers 32 may communicate with one another via one or more electronic networks 31, which may be in various embodiments any of the Internet, a wide area network, a mobile telephony network (such as CDMA or GSM cellular networks), a wireless network (such as WiFi, WiMAX, LTE, and so forth), or a local area network (or indeed any network topology known in the art; the aspect does not prefer any one network topology over any other). Networks 31 may be implemented using any known network protocols, including for example wired and/or wireless protocols.

In addition, in some embodiments, servers 32 may call external services 37 when needed to obtain additional information, or to refer to additional data concerning a particular call. Communications with external services 37 may take place, for example, via one or more networks 31. In various embodiments, external services 37 may comprise web-enabled services or functionality related to or installed on the hardware device itself. For example, in one aspect where client applications 24 are implemented on a smartphone or other electronic device, client applications 24 may obtain information stored in a server system 32 in the cloud or on an external service 37 deployed on one or more of a particular enterprise’s or user’s premises.

In some embodiments, clients 33 or servers 32 (or both) may make use of one or more specialized services or appliances that may be deployed locally or remotely across one or more networks 31. For example, one or more databases 34 may be used or referred to by one or more embodiments. It should be understood by one having ordinary skill in the art that databases 34 may be arranged in a wide variety of architectures and using a wide variety of data access and manipulation means. For example, in various embodiments one or more databases 34 may comprise a relational database system using a structured query language (SQL), while others may comprise an alternative data storage technology such as those referred to in the art as “NoSQL” (for example, HADOOP CASSANDRA®, GOOGLE BIGTABLE®, and so forth). In some embodiments, variant database architectures such as column-oriented databases, in-memory databases, clustered databases, distributed databases, or even flat file data repositories may be used according to the aspect. It will be appreciated by one having ordinary skill in the art that any combination of known or future database technologies may be used as appropriate, unless a specific database technology or a specific arrangement of components is specified for a particular aspect described herein. Moreover, it should be appreciated that the term “database” as used herein may refer to a physical database machine, a cluster of machines acting as a single database system, or a logical database within an overall database management system. Unless a specific meaning is specified for a given use of the term “database”, it should be construed to mean any of these senses of the word, all of which are understood as a plain meaning of the term “database” by those having ordinary skill in the art.

Similarly, some embodiments may make use of one or more security systems 36 and configuration systems 35. Security and configuration management are common information technology (IT) and web functions, and some amount of each are generally associated with any IT or web systems. It should be understood by one having ordinary skill in the art that any configuration or security subsystems known in the art now or in the future may be used in conjunction with embodiments without limitation, unless a specific security 36 or configuration system 35 or approach is specifically required by the description of any specific aspect.

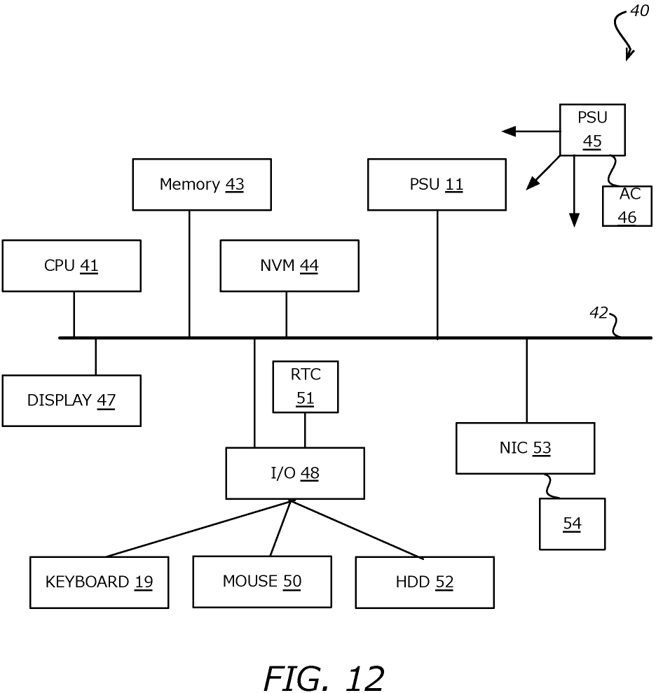

FIG. 12 shows an exemplary overview of a computer system 40 as may be used in any of the various locations throughout the system. It is exemplary of any computer that may execute code to process data. Various modifications and changes may be made to computer system 40 without departing from the broader scope of the system and method disclosed herein. Central processor unit (CPU) 41 is connected to bus 42, to which bus is also connected memory 43, nonvolatile memory 44, display 47, input/output (I/O) unit 48, and network interface card (NIC) 53. I/O unit 48 may, typically, be connected to keyboard 19, pointing device 50, hard disk 52, and real-time clock 51. NIC 53 connects to network 54, which may be the Internet or a local network, which local network may or may not have connections to the Internet. Also shown as part of system 40 is power supply unit 45 connected, in this example, to a main alternating current (AC) supply 46. Not shown are batteries that could be present, and many other devices and modifications that are well known but are not applicable to the specific novel functions of the current system and method disclosed herein. It should be appreciated that some or all components illustrated may be combined, such as in various integrated applications, for example Qualcomm or Samsung system-on-a-chip (SOC) devices, or whenever it may be appropriate to combine multiple capabilities or functions into a single hardware device (for instance, in mobile devices such as smartphones, video game consoles, in-vehicle computer systems such as navigation or multimedia systems in automobiles, or other integrated hardware devices).

In various embodiments, functionality for implementing systems or methods of various embodiments may be distributed among any number of client and/or server components. For example, various software modules may be implemented for performing various functions in connection with the system of any particular aspect, and such modules may be variously implemented to run on server and/or client components.

The skilled person will be aware of a range of possible modifications of the various embodiments described above. Accordingly, the present invention is defined by the claims and their equivalents.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and Bis false (or not present), A is false ( or not present) and Bis true ( or present), and both A and B are true ( or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

Upon reading this disclosure, those of skill in the art will appreciate still additional alternative structural and functional designs for a system and a process for collaborative text detection and recognition through the disclosed principles herein. Thus, while particular embodiments and applications have been illustrated and described, it is to be understood that the disclosed embodiments are not limited to the precise construction and components disclosed herein. Various apparent modifications, changes and variations may be made in the arrangement, operation and details of the method and apparatus disclosed herein without departing from the spirit and scope defined in the appended claims.

Accordingly, one or more different embodiments may be described in the present application. Further, for one or more of the embodiments described herein, numerous alternative arrangements may be described; it should be appreciated that these are presented for illustrative purposes only and are not limiting of the embodiments contained herein or the claims presented herein in any way. One or more of the arrangements may be widely applicable to numerous embodiments, as may be readily apparent from the disclosure. In general, arrangements are described in sufficient detail to enable those skilled in the art to practice one or more of the embodiments, and it should be appreciated that other arrangements may be utilized and that structural, logical, software, electrical and other changes may be made without departing from the scope of the embodiments. Particular features of one or more of the embodiments described herein may be described with reference to one or more particular embodiments or figures that form a part of the present disclosure, and in which are shown, by way of illustration, specific arrangements of one or more of the aspects. It should be appreciated, however, that such features are not limited to usage in the one or more particular embodiments or figures with reference to which they are described. The present disclosure is neither a literal description of all arrangements of one or more of the embodiments nor a listing of features of one or more of the embodiments that must be present in all arrangements.

Headings of sections provided in this patent application and the title of this patent application are for convenience only and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible embodiments and in order to more fully illustrate one or more embodiments. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the embodiments, and does not imply that the illustrated process is preferred. Also, steps are generally described once per aspect, but this does not mean they must occur once, or that they may only occur once each time a process, method, or algorithm is carried out or executed. Some steps may be omitted in some embodiments or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other embodiments need not include the device itself.

Techniques and mechanisms described or referenced herein will sometimes be described in singular form for clarity. However, it should be appreciated that particular embodiments may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various embodiments in which, for example, functions may be executed out of order from that shown or discussed, including substantially concurrently or in reverse order, depending on the functionality involved, as would be understood by those having ordinary skill in the art.

What is claimed is:

1. A computing system, comprising:
a computing device processor; and
a memory device including instructions that, when executed by the computing device processor, enables the computing system to:
obtain sensor data within a field of view of at least one camera of an unmanned aerial vehicle (UVA), the sensor data including a representation of a physical space that includes a construction site, a representation of a physical target object located at the construction site, and a representation of a physical marker located at the construction site,
analyze the sensor data using at least one object recognition algorithm to recognize the physical target object and the physical marker, the sensor data comprising first physical properties associated with the physical target object and the physical marker,
obtain construction site data for the construction site, the construction site data comprising physical design plans associated with the construction site, a representation of an object, and a representation of a reference marker, the physical design plans comprising second physical properties associated with the object and the reference marker,
map the sensor data and the construction site data to a reference coordinate system based on the representation of the physical marker in the sensor data and the representation of the reference marker in the construction site data,
compare the first physical properties of the physical target object represented in the sensor data with the second physical properties of the object represented in the construction site data to determine an offset between a physical property of the physical target object in the sensor data and a corresponding physical property of the object in the construction site data,
determine the offset satisfies a threshold, and
generate a report that indicates a discrepancy between the physical target object represented in the sensor data and the object represented in the construction site data.

2. The computing system of claim 1, wherein the discrepancy indicates that one of a pipe sleeve or a pipe is located in an incorrect location.

3. The computing system of claim 1, wherein the report indicates a location of the discrepancy.

4. The computing system of claim 1, wherein the physical target object or the object include one of a pipe sleeve, pipe, a structural beam, a wall, a door frame, a walkway, building foundation, or construction equipment.

5. The computing system of claim 1, wherein the construction site data comprises computer-aided design (CAD) data, the CAD data specifying the second physical properties and a label for the object and the reference marker.

6. The computing system of claim 1, wherein the first physical properties and the second physical properties comprise dimension information, shape information, or location information.

7. The computing system of claim 1, wherein the instructions, when executed by the computing device processor, further enables the computing system to:
obtain training data that includes image data corresponding to a plurality of objects associated with a construction site, the image data being associated with label data that specifies an object type of each one of the plurality of objects, and
train a model using the training data to generate a trained object detection model to recognize objects represented in image data.

8. The computing system of claim 1, wherein the instructions, when executed by the computing device processor, further enables the computing system to:
execute an image processing technique to identify an object type represented in the sensor data.

9. The computing system of claim 1, wherein the sensor data comprises at least one of two-dimensional data, three-dimensional point data, RFID, radar data, depth data, infrared, light coding data, or LIDAR.

10. The computing system of claim 1, wherein the instructions, when executed by the computing device processor, further enables the computing system to:
determine a mapping between feature points of the physical marker represented in the sensor data and the reference marker represented by the construction site data,
generate a rectifying model based on the mapping, and
apply the rectifying model to the sensor data and construction site data to reduce misalignment.

11. A computer-implemented method, comprising:
obtaining sensor data within a field of view of at least one camera of an unmanned aerial vehicle (UVA), the sensor data including a representation of a physical space that includes a construction site, a representation of a physical target object located at the construction site, and a representation of a physical marker located at the construction site,
analyzing the sensor data using at least one object recognition algorithm to recognize the physical target object and the physical marker, the sensor data comprising first physical properties associated with the physical target object and the physical marker,
obtaining construction site data for the construction site, the construction site data comprising physical design plans associated with the construction site, a representation of an object, and a representation of a reference marker, the physical design plans comprising second physical properties associated with the object and the reference marker,
mapping the sensor data and the construction site data to a reference coordinate system based on the representation of the physical marker in the sensor data and the representation of the reference marker in the construction site data;
comparing the first physical properties of the physical target object represented in the sensor data with the second physical properties of the object represented in the construction site data to determine an offset between a physical property of the physical target object in the sensor data and a corresponding physical property of the object in the construction site data,
determining the offset satisfies a threshold, and
generating a report that indicates a discrepancy between the physical target object represented in the sensor data and the object represented in the construction site data.

12. The computer-implemented method of claim 11, wherein the discrepancy indicates that one of a pipe sleeve or a pipe is located in an incorrect location.

13. The computer-implemented method of claim 11, wherein the report indicates a location of the discrepancy.

14. The computer-implemented method of claim 11, further comprising:
determining a mapping between feature points of the physical marker represented in the sensor data and the reference marker represented by the construction site data,
generating a rectifying model based on the mapping, and
applying the rectifying model to the sensor data and construction site data to reduce misalignment.

15. The computer-implemented method of claim 11, further comprising:
obtaining training data that includes image data corresponding to a plurality of objects associated with a construction site, the image data being associated with label data that specifies an object type of each one of the plurality of objects, and
training a model using the training data to generate a trained object detection model to recognize objects represented in image data.

16. The computer-implemented method of claim 11, further comprising:
executing an image processing technique to identify an object type represented in the sensor data.

17. A non-transitory computer readable storage medium storing instructions that, when executed by at least one processor of a computing system, causes the computing system to:
obtain sensor data within a field of view of at least one camera of an unmanned aerial vehicle (UVA), the sensor data including a representation of a physical space that includes a construction site, a representation of a physical target object located at the construction site, and a representation of a physical marker located at the construction site,
analyze the sensor data using at least one object recognition algorithm to recognize the physical target object and the physical marker, the sensor data comprising first physical properties associated with the physical target object and the physical marker,
obtain construction site data for the construction site, the construction site data comprising physical design plans associated with the construction site, a representation of an object, and a representation of a reference marker, the physical design plans comprising second physical properties associated with the object and the reference marker,
map the sensor data and the construction site data to a reference coordinate system based on the representation of the physical marker in the sensor data and the representation of the reference marker in the construction site data;
compare the first physical properties of the physical target object represented in the sensor data with the second physical properties of the object represented in the construction site data to determine an offset between a physical property of the physical target object in the sensor data and a corresponding physical property of the object in the construction site data,
determine the offset satisfies a threshold, and
generate a report that indicates a discrepancy between the physical target object represented in the sensor data and the object represented in the construction site data.

18. The non-transitory computer readable storage medium of claim 17, wherein the instructions, when executed by the at least one processor, further enables the computing system to:
obtain training data that includes image data corresponding to a plurality of objects associated with a construction site, the image data being associated with label data that specifies an object type of each one of the plurality of objects, and
train a model using the training data to generate a trained object detection model to recognize objects represented in sensor data.

19. The non-transitory computer readable storage medium of claim 17, wherein the instructions, when executed by the at least one processor, further enables the computing system to:
execute an image processing technique to identify an object type represented in the sensor data.

20. The non-transitory computer readable storage medium of claim 17, wherein the instructions, when executed by the at least one processor, further enables the computing system to:
determine a mapping between feature points of the physical marker represented in the sensor data and the reference marker represented by the construction site data,
generate a rectifying model based on the mapping, and
apply the rectifying model to the sensor data and construction site data to reduce misalignment.
